(19) United States
(12) Patent Application Publication
(10) Pub. No.: US 2023/0337498 A1
(43) Pub. Date: Oct. 19, 2023

(54) PIXEL ARRANGEMENT STRUCTURE, DISPLAY PANEL AND DISPLAY APPARATUS

(71) Applicant: KunShan Go-Visionox Opto-Electronics Co., Ltd, Kunshan (CN)

(72) Inventor: Zeming YANG, Kunshan (CN)

(73) Assignee: KunShan Go-Visionox Opto-Electronics Co., Ltd, Kunshan (CN)

(21) Appl. No.: 18/340,288

(22) Filed: Jun. 23, 2023

Related U.S. Application Data
(63) Continuation of application No. PCT/CN2021/137171, filed on Dec. 10, 2021.

(30) Foreign Application Priority Data
Mar. 30, 2021 (CN) 202110338433.8

(51) Int. Cl. H10K 59/35; H10K 59/131

(52) U.S. Cl. CPC H10K 59/353; H10K 59/131

(57) ABSTRACT

A pixel arrangement structure, a display panel, and a display apparatus. The pixel arrangement structure includes: a plurality of first pixel units each including at least two first sub-pixels, and at least two second sub-pixels and at least one third sub-pixel with different colors. A ratio of numbers of the at least two first sub-pixels, the at least two second sub-pixels and the at least one third sub-pixel is 2:2:1. At least two first sub-pixels and the at least two second sub-pixels are arranged alternately around the at least one third sub-pixel, and connecting lines between central points of the at least two first sub-pixels and central points of the at least two second sub-pixels form a polygon; a plurality of second pixel units each arranged between adjacent first pixel units along the row direction and the column direction.

### CROSS-REFERENCE TO RELATED APPLICATIONS

The present application is a continuation of International Application No. PCT/CN2021/137171 filed on Dec. 10, 2021, which claims the benefit of priority to Chinese Patent Application No. 202110338433.8 filed on Mar. 30, 2021, and entitled “PIXEL ARRANGEMENT STRUCTURE, DISPLAY PANEL AND DISPLAY APPARATUS”, both of which are hereby incorporated by reference in their entireties.

### TECHNICAL FIELD

The present application relates to the technical field of electronic products, and particularly, to a pixel arrangement structure, a display panel and a display apparatus.

### BACKGROUND

Compared with the existing mainstream flat panel display technology, the organic light emitting diode (OLED) has many advantages such as high contrast, wide viewing angle, low power consumption, and thinner volume. However, due to the manufacturing process of the OLED and the characteristics of the existing pixel arrangement, there are still some problems to be solved urgently in the OLED screen.

Due to the limitation of the fine metal mask (FMM) evaporation process and the pixel arrangement structure, the display panel has a low pixel density, making the high resolution difficult to achieve. Due to the limitation of the existing pixel arrangement structure, under a condition that patterns such as particular characters and lines are displayed, a phenomenon of sawtooth may occur, or the alternation of brightness and darkness may exist in the same pixel, and under a condition that the OLED screen displays a solid color image, alternate bright and dark stripes may occur, affecting the display effect of the image.

Therefore, a new pixel arrangement structure, a new display panel, and a new display apparatus are urgently needed.

### SUMMARY

Embodiments of the present application provide a pixel arrangement structure, a display panel and a display apparatus. The pixel arrangement structure can make sub-pixels to be arranged closely to each other, so that a high resolution is achieved, and meanwhile, occurrence of bright and dark stripes may be avoided when an image is displayed, thereby improving a display effect of an image.

In a first aspect, the embodiments of the present application provide a pixel arrangement structure including: a plurality of first pixel units each including at least two first sub-pixels, at least two second sub-pixels and at least one third sub-pixel with different colors, wherein a ratio of numbers of the at least two first sub-pixels, the at least two second sub-pixels and the at least one third sub-pixel is 2:2:1, wherein the at least two first sub-pixels and the at least two second sub-pixels are arranged alternately around the at least one third sub-pixel, and connecting lines between central points of the at least two first sub-pixels and central points of the at least two second sub-pixels form a polygon, wherein connecting lines between central points of the first sub-pixels and central points of the second sub-pixels adjacent to the first sub-pixels form polylines along at least one of a row direction and a column direction; a plurality of second pixel units each arranged between adjacent first pixel units along the row direction and the column direction.

In a second aspect, the embodiments of the present application further provide a display panel including the pixel arrangement structure in the above embodiments.

In a third aspect, the embodiments of the present application further provide a display apparatus including the display panel in the above embodiments.

Compared with the prior art, the pixel arrangement structure according to the embodiments of the present application includes the first pixel units and the second pixel units, the at least two first sub-pixels and the at least two second sub-pixels are arranged alternately around the at least one third sub-pixel, and connecting lines between central points of the at least two first sub-pixels and central points of the at least two second sub-pixels 2 form a polygon such as a parallelogram. Therefore, the third sub-pixels are arranged adjacent to the first sub-pixels and the second sub-pixels, thereby reducing an arrangement gap between sub-pixels, and improving the pixel density and the resolution. Connecting lines between central points of the first sub-pixels and central points of the second sub-pixels adjacent to the first sub-pixels form polylines along at least one of a row direction and a column direction. Specifically, along the row direction and/or the column direction, adjacent first sub-pixel and second sub-pixel are arranged alternately, rather than being arranged along a same straight line, so that the first sub-pixels and the second sub-pixels are distributed more evenly, thereby avoiding a concentration of the first sub-pixels and the second sub-pixels on the same straight line along the row direction and/or the column direction as well as a formation of bright and dark stripes between the first sub-pixels/the second sub-pixels and the third sub-pixels, and improving a display effect of the display panel.

### BRIEF DESCRIPTION OF THE DRAWINGS

FIG. 1 is a schematic structural view of a pixel arrangement structure according to an embodiment of the present application.

FIG. 2 is a schematic structural view of a first pixel unit according to an embodiment of the present application.

FIG. 3 is a schematic structural view of a pixel arrangement structure according to another embodiment of the present application.

FIG. 4 is a schematic structural view of a first pixel unit according to another embodiment of the present application.

FIG. 5 is a schematic structural view of a pixel arrangement structure according to yet another embodiment of the present application.

FIG. 6 is a schematic structural view of a first pixel unit according to yet another embodiment of the present application.

FIG. 7 is a schematic view of a diagonal pixel arrangement structure according to an embodiment of the present application.

### DETAILED DESCRIPTION

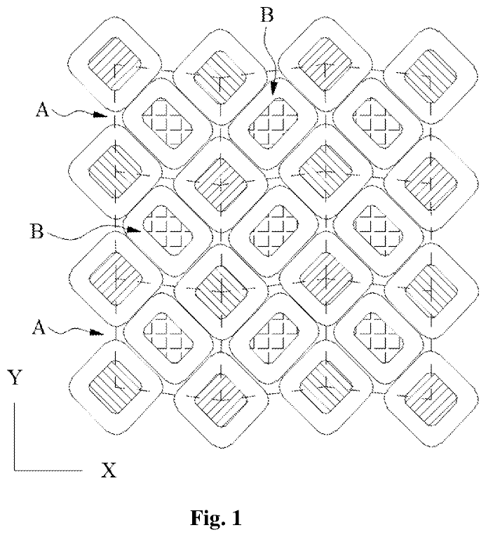

For a better understanding of the present application, a pixel arrangement structure, a display panel, and a display apparatus according to embodiments of the present application will be described in detail with reference to FIG. 1 to FIG. 7.

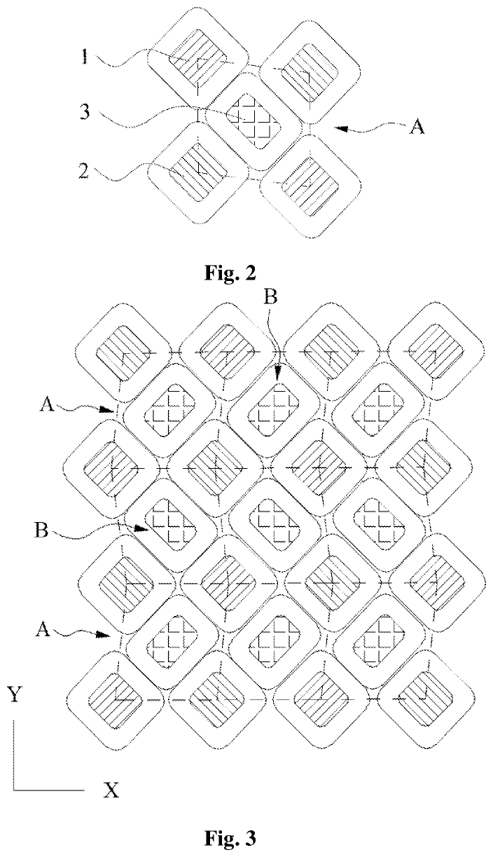

With reference to FIG. 1 and FIG. 2, the embodiments of the present application provides a pixel arrangement structure. The pixel arrangement structure includes: a plurality of first pixel units A each including at least two first sub-pixels 1, at least two second sub-pixels 2 and at least one third sub-pixel 1 with different colors, wherein a ratio of numbers of the at least two first sub-pixels 1, the at least two second sub-pixels 2 and the at least one third sub-pixel 1 is 2:2:1, wherein the at least two first sub-pixels 1 and the at least two second sub-pixels 2 are arranged alternately around the at least one third sub-pixel 1, connecting lines between central points of the at least two first sub-pixels 1 and central points of the at least two second sub-pixels 2 form a polygon, and each of the second pixel units B includes the third sub-pixel 3, wherein connecting lines between central points of the first sub-pixels 1 and central points of the second sub-pixels 2 adjacent to the first sub-pixels 1 form polylines along at least one of a row direction X and a column direction Y; a plurality of second pixel units B each arranged between adjacent first pixel units A along the row direction X and the column direction Y.

The pixel arrangement structure according to the embodiments of the present application includes the first pixel units A and the second pixel units B, the at least two first sub-pixels 1 and the at least two second sub-pixels 2 are arranged alternately around the at least one third sub-pixel 3, and connecting lines between central points of the at least two first sub-pixels 1 and central points of the at least two second sub-pixels 2 form a polygon such as a parallelogram. Therefore, the third sub-pixels 3 are arranged adjacent to the first sub-pixels 1 and the second sub-pixels 2, thereby reducing an arrangement gap between the sub-pixels, and improving the pixel density and the resolution. Connecting lines between central points of the first sub-pixels 1 and central points of the second sub-pixels 2 adjacent to the first sub-pixels 1 form polylines along at least one of the row direction X and the column direction Y. Specifically, along the row direction X and/or the column direction Y, adjacent first sub-pixel 1 and second sub-pixel 2 are arranged alternately, rather than being arranged along a same straight line, so that the first sub-pixels 1 and the second sub-pixels 2 are distributed more evenly, thereby avoiding a concentration of the first sub-pixels 1 and the second sub-pixels 2 on the same straight line along the row direction X and/or the column direction Y as well as a formation of bright and dark stripes between the first sub-pixels 1/the second sub-pixels 2 and the third sub-pixels 3, and improving a display effect of the display panel.

It should be noted that, in the embodiments of the present application, the pixel arrangement structure is divided into the first pixel units A and the second pixel units B, and each of the first pixel units A includes one third sub-pixel 3 as well as two first sub-pixels 1 and two second sub-pixels 2 arranged alternately around the one third sub-pixel 3. In fact, the pixel unit includes one first sub-pixel 1, one second sub-pixel 2 and one third sub-pixel 3 which are adjacent to each other, so that the first pixel unit A and the second pixel unit B jointly form two pixel units. The pixel units are distributed evenly by shifting the first pixel unit A and the second pixel unit B in a repeated manner along the row direction X and the column direction Y.

The first sub-pixel 1, the second sub-pixel 2 and the third sub-pixel 3 are arranged closely to each other within the pixel unit and between the pixel units to achieve a high resolution. With reference to FIG. 1, in the embodiments of the present application, connecting lines between central points of the at least two first sub-pixels 1 and the central points of the at least two second sub-pixels 2 form a polygon. Specifically, under a condition that the connecting lines between the central points of the first sub-pixels 1 and the central points of the second sub-pixels 2 form the polygon, the third sub-pixel 3 may more fit into angles of the polygon and be arranged at the center of the first pixel unit A. Meanwhile, the third sub-pixel 3 in the second pixel unit B may be arranged more closely to the first sub-pixels 1 and the second sub-pixels 2 in its adjacent first pixel unit A, so that the arrangement gap between the sub-pixels is reduced, thereby improving the pixel density and the resolution.

Furthermore, in order to avoid that the first sub-pixel 1, the second sub-pixel 2 and the third sub-pixel 3 in each pixel unit are distributed unevenly, which otherwise may cause occurrence of a significant brightness difference and occurrence of alternate bright and dark stripes in the pixel arrangement structure, in the embodiments of the present application, the connecting lines between the central points of the first sub-pixels 1 and the central points of the second sub-pixels 2 adjacent to the first sub-pixels 1 form the polylines along at least one of the row direction X and the column direction Y. Since the adjacent first sub-pixel 1 and second sub-pixel 2 are arranged alternately, rather than being concentrated on the same straight line, the first sub-pixels and the second sub-pixels in the pixel units are distributed more evenly, thereby avoiding the concentration of the first sub-pixels 1 and the second sub-pixels 2 on the same straight line along the row direction and/or the column direction as well as the formation of the significant brightness difference between the first sub-pixels 1/the second sub-pixels 2 and the third sub-pixels 3. Therefore, preventing occurrence of the alternate bright and dark stripes when a solid color image is displayed, thereby improving the quality of the image.

With reference to FIG. 1 and FIG. 2, in the embodiments of the present application, the connecting lines between the central points of the first sub-pixels 1 and the central points of the second sub-pixels 2 adjacent to the first sub-pixels 1 form polylines along the row direction X, and the connecting lines between the central points of the first sub-pixels 1 and the central points of the second sub-pixels 2 adjacent to the first sub-pixels 1 form straight lines along the column direction Y. Therefore, the first sub-pixel 1 and the second sub-pixel 2 in each first pixel unit A are arranged alternately along the row direction X, and there is no condition under which light-emitting centers of the first sub-pixels 1 and the second sub-pixels 2 are located on a same row. That is, the formation of bright and dark stripes between the first sub-pixels 1/the second sub-pixels 2 and the third sub-pixels 3 along the column direction Y is avoided, thereby improving the display effect of the display panel.

In some optional embodiments, extending directions of two adjacent second pixel units located on a same column are parallel, so that the second pixel units B are distributed in a more regular manner.

As shown in FIG. 1, in order to improve evenness of distribution of the second pixel units B, optionally, the plurality of first pixel units A are arranged in an array along the row direction X and the column direction Y, and the plurality of second pixel units B include a plurality of first type pixel units arranged in rows and each located between two adjacent rows of the first pixel units A along the column direction Y as well as a plurality of second type pixel units each located between two adjacent first pixel units A along the row direction X, and extending directions of two adjacent first type pixel units located on a same row intersect with each other.

It is understood that the first type pixel units are located between the two adjacent rows of the first pixel units A, and the second type pixel units are located between the two adjacent columns of the first pixel unit A, so that the first type pixel units and the second type pixel units cooperate with the first pixel units A to achieve a mixing of light, and in the embodiment, the extending directions of the two adjacent first type pixel units located on the same row intersect with each other, thereby improving the evenness of the distribution of the first type pixel units. Optionally, the first type pixel unit and the second type pixel unit may be in shapes including rectangles and parallelograms in same or different shapes, which are not particularly limited.

It is understood that the connecting lines between the central points of the at least two first sub-pixels 1 and the central points of the at least two second sub-pixels 2 in the first pixel unit A form various polygons including a trapezium or a parallelogram, that is, the connecting lines between the central points of the first sub-pixels 1 and the central points of the second sub-pixels 2 adjacent to the first sub-pixels 1 form the polylines along at least one of the row direction X and the column direction Y.

For convenience of illustration, with reference to FIG. 1, in the embodiments of the present application, the connecting lines between the central points of the at least two first sub-pixels 1 and the central points of the at least two second sub-pixels 2 form a parallelogram. Specifically, the first pixel unit A includes two first sub-pixels 1, two second sub-pixels 2 and one third sub-pixel 3, central points of the two first sub-pixels 1 constitute vertices of one set of diagonal angles of a parallelogram, central points of the two second sub-pixels 2 constitute vertices of the other set of diagonal angles of the parallelogram, and the third sub-pixel 3 is located in a region surrounded by the first sub-pixels and the second sub-pixels, that is, the third sub-pixel 3 is located at the center of the parallelogram. The polygon is a parallelogram, so that a gap between adjacent sub-pixels can be effectively ensured to be consistent and relatively small, an aperture ratio of the pixel arrangement structure is improved. Compared to the embodiments in which a trapezoid is used, problems such as uneven brightness, bright and dark spots or stripes caused by inconsistency of the gap between sub-pixels are effectively avoided.

In the embodiment, the central points of the two first sub-pixels 1 constitute an acute angle of the parallelogram, and the central points of the two second sub-pixels 2 constitute an obtuse angle of the parallelogram. Optionally, the acute angle is 83°, and the obtuse angle is 97°, and the acute angle and the obtuse angle of the parallelogram may be set to be other degrees, which are not specifically limited herein.

It is noted that, with reference to FIG. 1, under a condition that the connecting lines between the central points of the at least two first sub-pixels 1 and the central points of the at least two second sub-pixels 2 form a parallelogram, in order to achieve that the connecting lines between the central points of the first sub-pixels 1 and the central points of the second sub-pixels 2 adjacent to the first sub-pixels 1 form the polylines along the row direction X, two adjacent parallelograms form a symmetrical structure along the row direction X, that is, the third sub-pixels 3 in the adjacent first pixel unit A and the second pixel unit B form symmetrical structure along the row direction X. Meanwhile, since the connecting lines between the central points of the first sub-pixels 1 and the central points of the second sub-pixels 2 adjacent to the first sub-pixels 1 form the straight lines along the column direction Y, two adjacent parallelograms have a same structure along the column direction Y, that is, the third sub-pixels 3 in the adjacent first pixel unit A and the second pixel unit B have a same structure along the column direction Y. The pixel arrangement structure in the embodiments of the present application may be formed by shifting the first pixel unit A and the second pixel unit B in a repeated manner along the row direction X and the column direction Y.

In the embodiments of the present application, each of the first sub-pixel 1, the second sub-pixel 2 and the third sub-pixel 3 is polygonal in shape, so that the connecting lines between the central points of the at least two first sub-pixels 1 and the central points of the at least two second sub-pixels 2 form the parallelogram, and the at least two first sub-pixels 1 and the at least two second sub-pixels 2 are arranged around the at least one third sub-pixel 3 to reduce the arrangement gap between the sub-pixels and improve the pixel density. Furthermore, each of the first sub-pixel 1, the second sub-pixel 2 and the third sub-pixel 3 is rectangular in shape.

In the pixel arrangement structure according to an embodiment of the present application, the third sub-pixel 3 is a green sub-pixel. Under this condition, in order to prevent occurrence of a phenomenon of sawtooth, connecting lines between central points of third sub-pixels 3 should form straight lines along at least one of the row direction X and the column direction Y, so as to ensure that positions of light-emitting centers of the third sub-pixels 3 located on a same row/column are arranged on a same straight line, thereby improving the display effect when the third sub-pixels 3 display in a horizontal or vertical stripe.

Furthermore, in the embodiments of the present application, the first sub-pixel 1 is a red sub-pixel, the second sub-pixel 2 is a blue sub-pixel, and the third sub-pixel 3 is a green sub-pixel. Considering the lifetime and the color deviation of the screen, an opening of the second sub-pixel 2 is greater than an opening of the first sub-pixel 1 and an opening of the third sub-pixel 3. Specifically, since the blue sub-pixel has a strong light-emitting attenuation, the light-emitting lifetime of the second sub-pixel 2 can be increased under a condition that the opening of the second sub-pixel 2 is increased, so as to ensure consistency of light emitted by the first sub-pixel 1, the second sub-pixel 2 and the third sub-pixel 3, thereby improving the lifetime and the color deviation of the screen.

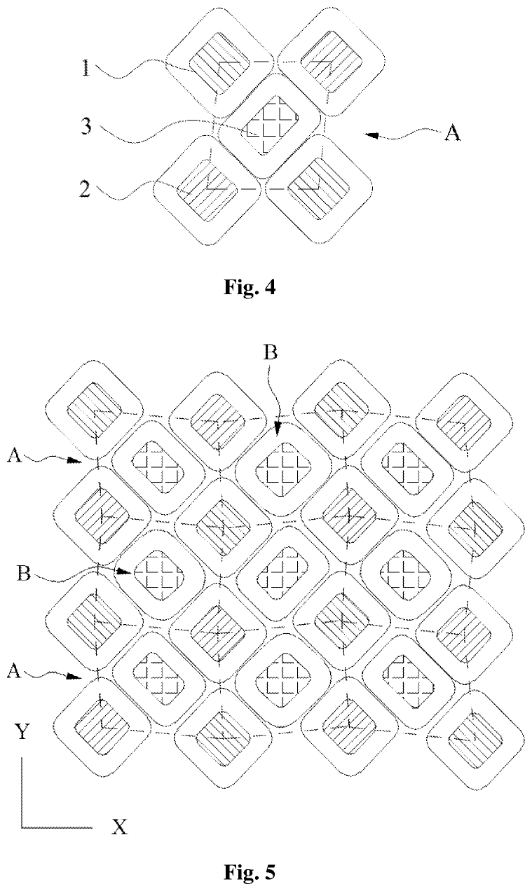

In some optional embodiments, as shown in FIG. 3 and FIG. 4, the connecting lines between the central points of the first sub-pixels 1 and the central points of the second sub-pixels 2 adjacent to the first sub-pixels 1 form straight lines along the row direction X, and the connecting lines between the central points of the first sub-pixels 1 and the central points of the second sub-pixels 2 adjacent to the first sub-pixels 1 form polylines along the column direction Y. Therefore, the first sub-pixel 1 and the second sub-pixel 2 in each first pixel unit A are arranged alternately along the column direction Y, and there is no condition under which the light-emitting centers of the first sub-pixels 1 and the second sub-pixels 2 are located on a same column. That is, the formation of the bright and dark stripes between the first sub-pixels 1/the second sub-pixels 2 and the third sub-pixels 3 along the row direction X is avoided, thereby improving the display effect of the display panel.

As shown in FIG. 3, optionally, in the embodiment, extending directions of two adjacent second pixel units B located on a same column intersect with each other, thereby preventing the first pixel unit A and the second pixel unit B from forming bright and dark stripes along the column direction Y, and improving the display effect of the display panel.

Specifically, the plurality of first pixel units are arranged in an array along the row direction X and the column direction Y, and the plurality of second pixel units B include a plurality of first type pixel units arranged in rows and each located between two adjacent rows of first pixel units A along the column direction Y as well as a plurality of second type pixel units each located between two adjacent first pixel units A along the row direction X, extending directions of the plurality of first type pixel units are parallel, extending directions of the plurality of second type pixel units are parallel, and the extending directions of the plurality of first type pixel units intersect with the extending directions of the plurality of second type pixel units.

In the embodiment, the extending directions of the plurality of first type pixel units of the second pixel units B intersect with the extending directions of the plurality of second type pixel units of the second pixel units B, so as to prevent the first pixel unit A and the second pixel unit B from forming the bright and dark stripes along the row direction X and the column direction Y, thereby improving the display effect of the display panel. Furthermore, under a condition that the connecting lines between the central points of the at least two first sub-pixels 1 and the central points of the at least two second sub-pixels 2 form a parallelogram, in order to achieve that the connecting lines between the central points of the first sub-pixels 1 and the central points of the second sub-pixels 2 adjacent to the first sub-pixels 1 form the polylines along the column direction Y, two adjacent parallelograms form a symmetrical structure along the column direction Y, that is, the third sub-pixels 3 in the adjacent first pixel unit A and the second pixel unit B form symmetrical structure along the column direction Y. Meanwhile, since the connecting lines between the central points of the first sub-pixels 1 and the central points of the second sub-pixels 2 adjacent to the first sub-pixels 1 form the straight lines along the row direction X, two adjacent parallelograms have a same structure along the row direction X, that is, the third sub-pixels 3 in the adjacent first pixel unit A and the second pixel unit B have a same structure along the row direction X. The pixel arrangement structure in the embodiments of the present application may be formed by shifting the first pixel unit A and the second pixel unit B in a repeated manner along the row direction X and the column direction Y.

It is understood that, positions of the first sub-pixel 1, the second sub-pixel 2 and the third sub-pixel 3 may be adjusted according to an actual display effect, that is, the connecting lines between the central points of the first sub-pixels 1 and the central points of the second sub-pixels 2 adjacent to the first sub-pixels 1 may form polylines along both the row direction X and the column direction Y.

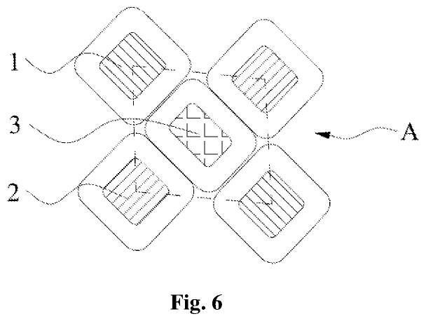

Therefore, in some optional embodiments, as shown in FIG. 5 and FIG. 6, the connecting lines between the central points of the first sub-pixels 1 and the central points of the second sub-pixels 2 adjacent to the first sub-pixels 1 may form the polylines along both the row direction X and the column direction Y. Therefore, the first sub-pixel 1 and the second sub-pixel 2 in each first pixel unit A are arranged alternately along the row direction X and the column direction Y, and there is no condition under which the light-emitting centers of the first sub-pixels 1 and the second sub-pixels 2 are located on a same row and a same column. That is, the formation of the bright and dark stripes between the first sub-pixels 1/the second sub-pixels 2 and the third sub-pixels 3 along the row direction X and the column direction Y is avoided, thereby improving the display effect of the display panel.

Optionally, in order to prevent the occurrence of the phenomenon of sawtooth, each of the second pixel units B includes one third sub-pixel 3, and connecting lines between central points of third sub-pixels 3 should form straight lines along at least one of a first direction Z and a direction perpendicular to the first direction Z, so as to ensure that positions of light-emitting centers of a same diagonal stripe are on a same straight line, thereby improving the display effect of the image.

As shown in FIG. 5, optionally, in the embodiment, third sub-pixels 3 of two adjacent second pixel units B have different shapes. The shapes of the third sub-pixels 3 of the two adjacent second pixel units B match the shapes of connecting lines between the central points of the first sub-pixels 1 and the second sub-pixels 2 adjacent to the third sub-pixels 3, which may specifically be rectangular, parallelogram and the like in shape.

Furthermore, under a condition that the connecting lines between the central points of the at least two first sub-pixels 1 and the central points of the at least two second sub-pixels 2 form a parallelogram, in order to achieve that the connecting lines between the central points of the first sub-pixels 1 and the central points of the second sub-pixels 2 adjacent to the first sub-pixels 1 form the polylines along the row direction X and the column direction Y, a shape of the third sub-pixel 3 in the first pixel unit A is different from a shape of the third sub-pixel 3 in the second pixel unit B, that is, the third sub-pixel 3 can fit into a gap formed by the first sub-pixels 1 and the second sub-pixels 2, and a specific shape the third sub-pixel 3 is not specifically defined here.

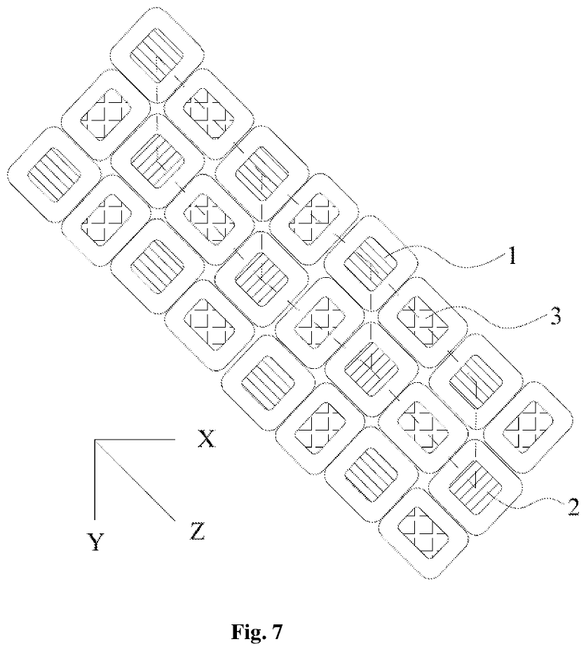

The above embodiments merely describe an arrangement of a pixel arrangement structure of a horizontal stripe and a vertical stripe, and under a condition that the pixel arrangement structure is arranged diagonally, with reference to FIG. 7, connecting lines between central points of adjacent first sub-pixels 1 form polylines along the first direction Z, and/or connecting lines between central points of adjacent second sub-pixels 2 form polylines along the first direction Z. An angle between the first direction Z and the row direction X is equal to an angle between the first direction Z and the column direction Y. Positions of the first sub-pixel 1 and the second sub-pixel 2 are adjusted along the first direction Z, so that it is possible to ensure that the first sub-pixel 1, the second sub-pixel 2 and the third sub-pixel 3 form a transitional position relationship along the first direction Z, so as to avoid a relatively large gap existing between adjacent sub-pixels, thereby preventing occurrence of the bright and dark stripes on the solid color image along the first direction Z.

The embodiments of the present application further provide a display panel including the pixel arrangement structure in any one of the above embodiments. Since the display panel according to the embodiments of the present application includes the pixel arrangement structure in any one of the above embodiments, the display panel according to the present application has the beneficial effects of the pixel arrangement structure in any one of the above embodiments, which will not be repeated here.

Furthermore, the embodiments of the present application further provide a display apparatus including a display panel. Pixels of a display panel of a display apparatus are formed by using the above pixel arrangement structure, and the display apparatus is applicable to any display apparatus composed of red, green, and blue sub-pixels, such as a liquid crystal display (LCD) apparatus, an OLED display apparatus, or the like.

The display apparatus according to the embodiment of the present application has the technical effect of the technical solution of the display panel in any one of the above embodiments, and the explanations of structures and terms that are the same or corresponding to the above embodiments are not repeated here. The display apparatus according to the embodiment of the present application may be a mobile phone, and may also be any electronic product with a display function, including but not limited to the following categories: televisions, notebook computers, desktop displays, tablet computers, digital cameras, smart bracelets, smart glasses, vehicle-mounted displays, medical equipment, industrial control equipment, touch interactive terminals, and the like, which are not particularly limited in the embodiment of the present application.

What is claimed is:

1. A pixel arrangement structure, comprising:
a plurality of first pixel units each comprising at least two first sub-pixels, at least two second sub-pixels and at least one third sub-pixel with different colors, wherein a ratio of numbers of the at least two first sub-pixels, the at least two second sub-pixels and the at least one third sub-pixel is 2:2:1, wherein the at least two first sub-pixels and the at least two second sub-pixels are arranged alternately around the at least one third sub-pixel, and connecting lines between central points of the at least two first sub-pixels and central points of the at least two second sub-pixels form a polygon,
wherein connecting lines between central points of the first sub-pixels and central points of the second sub-pixels adjacent to the first sub-pixels form polylines along at least one of a row direction and a column direction;
a plurality of second pixel units each arranged between adjacent first pixel units along the row direction and the column direction.

2. The pixel arrangement structure according to claim 1, wherein the first pixel unit comprises two first sub-pixels, two second sub-pixels and one third sub-pixel, central points of the two first sub-pixels constitute vertices of one set of diagonal angles of a parallelogram, central points of the two second sub-pixels constitute vertices of the other set of diagonal angles of the parallelogram, and the third sub-pixel is located in a region surrounded by the first sub-pixels and the second sub-pixels.

3. The pixel arrangement structure according to claim 1, wherein the connecting lines between the central points of the first sub-pixels and the central points of the second sub-pixels adjacent to the first sub-pixels form polylines along the row direction, and the connecting lines between the central points of the first sub-pixels and the central points of the second sub-pixels adjacent to the first sub-pixels form straight lines along the column direction.

4. The pixel arrangement structure according to claim 1, wherein the connecting lines between the central points of the first sub-pixels and the central points of the second sub-pixels adjacent to the first sub-pixels form straight lines along the row direction, and the connecting lines between the central points of the first sub-pixels and the central points of the second sub-pixels adjacent to the first sub-pixels form polylines along the column direction.

5. The pixel arrangement structure according to claim 1, wherein the connecting lines between the central points of the first sub-pixels and the central points of the second sub-pixels adjacent to the first sub-pixels form polylines along both the row direction and the column direction.

6. The pixel arrangement structure according to claim 1, wherein the connecting lines between the central points of the at least two first sub-pixels and the central points of the at least two second sub-pixels form a trapezium or a parallelogram.

7. The pixel arrangement structure according to claim 1, wherein extending directions of two adjacent second pixel units located on a same column are parallel.

8. The pixel arrangement structure according to claim 7, wherein the plurality of first pixel units are arranged in an array along the row direction and the column direction, and the plurality of second pixel units comprise a plurality of first type pixel units arranged in rows and each located between two adjacent rows of the first pixel units along the column direction as well as a plurality of second type pixel units each located between two adjacent first pixel units along the row direction, and extending directions of two adjacent first type pixel units located on a same row intersect with each other.

9. The pixel arrangement structure according to claim 1, wherein extending directions of two adjacent second pixel units located on a same column intersect with each other.

10. The pixel arrangement structure according to claim 9, wherein the plurality of first pixel units are arranged in an array along the row direction and the column direction, and the plurality of second pixel units comprise a plurality of first type pixel units arranged in rows and each located between two adjacent rows of first pixel units along the column direction as well as a plurality of second type pixel units each located between two adjacent first pixel units along the row direction, extending directions of the plurality of first type pixel units are parallel, extending directions of the plurality of second type pixel units are parallel, and the extending directions of the plurality of first type pixel units intersect with the extending directions of the plurality of second type pixel units.

11. The pixel arrangement structure according to claim 1, wherein each of the second pixel units comprises one third sub-pixel, and connecting lines between central points of third sub-pixels form straight lines along at least one of the row direction and the column direction.

12. The pixel arrangement structure according to claim 10, wherein third sub-pixels of two adjacent second pixel units have different shapes.

13. The pixel arrangement structure according to claim 1, wherein the first sub-pixel is a red sub-pixel, the second sub-pixel is a blue sub-pixel, the third sub-pixel is a green sub-pixel, and an opening of the second sub-pixel is greater than an opening of the first sub-pixel and an opening of the third sub-pixel.

14. The pixel arrangement structure according to claim 1, wherein each of the first sub-pixel, the second sub-pixel and the third sub-pixel is polygonal in shape.

15. The pixel arrangement structure according to claim 14, wherein each of the first sub-pixel, the second sub-pixel and the third sub-pixel is rectangular in shape.

16. The pixel arrangement structure according to claim 1, wherein connecting lines between central points of adjacent first sub-pixels form polylines along a first direction.

17. The pixel arrangement structure according to claim 1, wherein connecting lines between central points of adjacent second sub-pixels form polylines along a first direction, and an angle between the first direction and the row direction is equal to an angle between the first direction and the column direction.

18. A display panel comprising the pixel arrangement structure according to claim 1.

19. A display apparatus comprising the display panel of claim 18.
